(19) United States
(12) Patent Application Publication
(10) Pub. No.: US 2015/0028204 A1
(43) Pub. Date: Jan. 29, 2015

(54) INSPECTION APPARATUS AND INSPECTION METHOD

(71) Applicant: Kabushiki Kaisha Toshiba, Minato-ku (JP)

(72) Inventor: Kazuhiro NOJIMA, Yokkaichi-shi (JP)

(73) Assignee: Kabushiki Kaisha Toshiba, Minato-ku (JP)

(21) Appl. No.: 14/200,324

(22) Filed: Mar. 7, 2014

Related U.S. Application Data
(60) Provisional application No. 61/858,167, filed on Jul. 25, 2013.

(51) Int. Cl. H01J 37/26

(52) U.S. Cl. CPC H01J 37/26
USPC 250/307; 250/310

(57) ABSTRACT

In accordance with an embodiment, an inspection apparatus includes first and second charged particle beam application units to apply charged particle beams to a sample, a detector, an image acquiring unit, and a judgment unit. The sample includes a stack structure in which electrically conductive films and insulating films are alternately stacked, electrically conductive layers, first and second contact plugs. The first charged particle beam application unit controls the potential of each electrically conductive film by applying a first charged particle beam to the second contact plugs. The second charged particle beam application unit applies a second charged particle beam to the first contact plugs. The detector detects secondary charged particles from the stack structure and outputs a signal. The image acquiring unit processes the signal to acquire a first image of the sample surface. The judgment unit judges an abnormality of the sample from the acquired first image.

### CROSS REFERENCE TO RELATED APPLICATIONS

This application is based upon and claims the benefit of U.S. provisional Application No. 61/858,167, filed on Jul. 25, 2013, the entire contents of which are incorporated herein by reference.

### FIELD

Embodiments described herein relate generally to an inspection apparatus and an inspection method.

### BACKGROUND

Semiconductor devices have heretofore been enhanced in integration and reduced in cost by process miniaturization. However, the miniaturization has been faced with a physical limit. Therefore, a device having a stack structure in which a large number of layers are vertically stacked has been developed.

A memory device is described by way of example. According to a manufacturing process of a memory device having a stack structure, insulating films and electrically conductive films are alternately deposited, and a memory hole is then formed at once in this stack by a dry etching method. A charge storage film and electrodes are then formed in the memory hole for element formation.

Manufacturing costs per bit can be reduced by the increase of the number of stacked layers. Thus, the number of stacked layers has been increasing, and a stack of several ten layers having a thickness of several micrometers has been developed at present.

In order to form the memory hole in the stack structure, it is necessary to sequentially form materials different in etching rate by the dry etching method. To this end, a plurality of repetitive processes with a controlled etching rate are performed. Here, an etching variation is a problem. This is because if there is etching remainder in the stacked film of the previous stage during the etching of the stacked film of the subsequent stage, the etching stops at this point, and the operation as a memory is prevented accordingly.

The optimization of an etching condition is required to improve yield. However, conventional defect inspection techniques have the following problems.

Firstly, a defect resulting from an etching failure is formed inside a structure. Therefore, according to a defect inspection technique that uses an electron beam, the penetration depth of the electron beam is smaller than that of light, and it is thus difficult to obtain inside information.

Secondly, a generally used electrically conductive layer is made of a semiconductor material such as polysilicon. Therefore, according to an inspection technique that uses light, electron/hole pairs are excited by the light, and further transmission of the light is impossible. As a result, it is difficult to obtain information regarding the inside of the structure. In particular, for the optimization of the etching condition, the layer in which the etching is stopped is important information in addition to the number of defects and the distribution of defects caused inside the wafer plane. However, according to the conventional techniques, it is difficult to obtain depth-direction information.

### BRIEF DESCRIPTION OF THE DRAWINGS

In the accompanying drawings:

FIG. 1 is a block diagram showing the general structure of an inspection apparatus according to an embodiment;

FIG. 2 is a partially enlarged diagram of FIG. 1; FIG. 3A is a sectional view illustrating a device structure of a sample;

FIG. 3B shows an equivalent circuit of a part of a stack structure shown in FIG. 3A;

FIG. 4 shows graphs representing an example of the changes of surface potentials of first contact plugs with time obtained in an inspection of a sample using the inspection apparatus shown in FIG. 1;

FIG. 5A is a graph showing the relation between energy of incoming electrons and a secondary electron emission coefficient;

FIG. 5B is a diagram illustrating the incoming electron energy dependence of the secondary electron emission coefficient;

FIG. 6 shows band diagrams each showing a vacuum level and a Fermi level in each charged state;

FIG. 7 is an example of a graph showing frequency dependence regarding a potential difference between a potential-controlled gate interconnection layer and a gate interconnection layer adjacent thereto;

FIG. 8A shows examples of potential contrast images; FIG. 8B is a sectional view showing an example of a memory cell different from a memory cell shown in FIG. 3A;

FIG. 8C shows an equivalent circuit of FIG. 8B;

FIG. 9A is a sectional view showing an example of a memory cell different from the memory cell shown in FIG. 3A; FIG. 9B shows an example of a change with time in a potential of each gate interconnection layer which is potential-controlled by the application of an electron beam to second contact plugs through an electric supply column;

FIG. 9C shows potential contrast images which are respectively cumulated in times shown in FIG. 9B; and

FIG. 10 is a flowchart showing a general procedure of an inspection method according to an embodiment.

### DETAILED DESCRIPTION

In accordance with an embodiment, an inspection apparatus includes first and second charged particle beam application units to apply first and second charged particle beams to a sample, respectively, a detector, an image acquiring unit, and a judgment unit. The sample includes a stack structure, electrically conductive layers, and first and second contact plugs. The electrically conductive films and insulating films are alternately stacked in the stack structure. The electrically conductive layers are provided in hole patterns formed in the stack structure in a stacking direction and are respectively connected to the electrically conductive films via a capacitance or a resistance. The first contact plugs are respectively connected to the electrically conductive layers. The second contact plugs are connected to the electrically conductive layers. The first charged particle beam application unit controls potentials of electrically conductive films by applying the first charged particle beam to the second contact plugs. The second charged particle beam application unit applies the second charged particle beam to the first contact plugs. The detector detects secondary charged particles generated from a surface of the stack structure to output a signal. The image acquiring unit processes the signal to acquire a first image of the sample surface. The judgment unit judges an abnormality of the hole pattern from the acquired first image.

Embodiments will now be explained with reference to the accompanying drawings. Like components are provided with like reference signs throughout the drawings and repeated descriptions thereof are appropriately omitted.

(A) Inspection Apparatus

(1) Apparatus Configuration

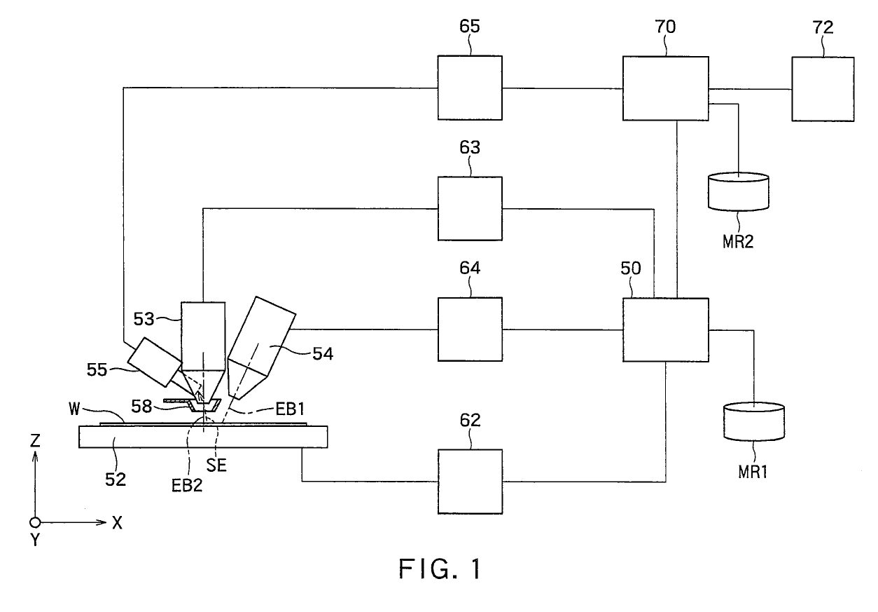

FIG. 1 is a block diagram showing the general structure of an inspection apparatus according to an embodiment. The inspection apparatus shown in FIG. 1 includes a stage 52, a stage drive control section 62, a control computer 50, an electric supply column 54, an electric supply column control section 64, a detection column 53, a detection column control section 63, a cantilever 58, a secondary electron detector 55, a signal processing section 65, a judgment section 70, and a monitor 72.

A wafer W is mounted on the upper surface of the stage 52, and the stage 52 holds this wafer W. The stage 52 is connected to the stage drive control section 62. In response to a control signal from the stage drive control section 62, the stage 52 uses an unshown actuator to move the wafer W in a three-dimensional space in an X-direction, a Y-direction, and a Z-direction, and also rotate the wafer W at a given rotation angle. This permits a wide-range inspection with a high throughput.

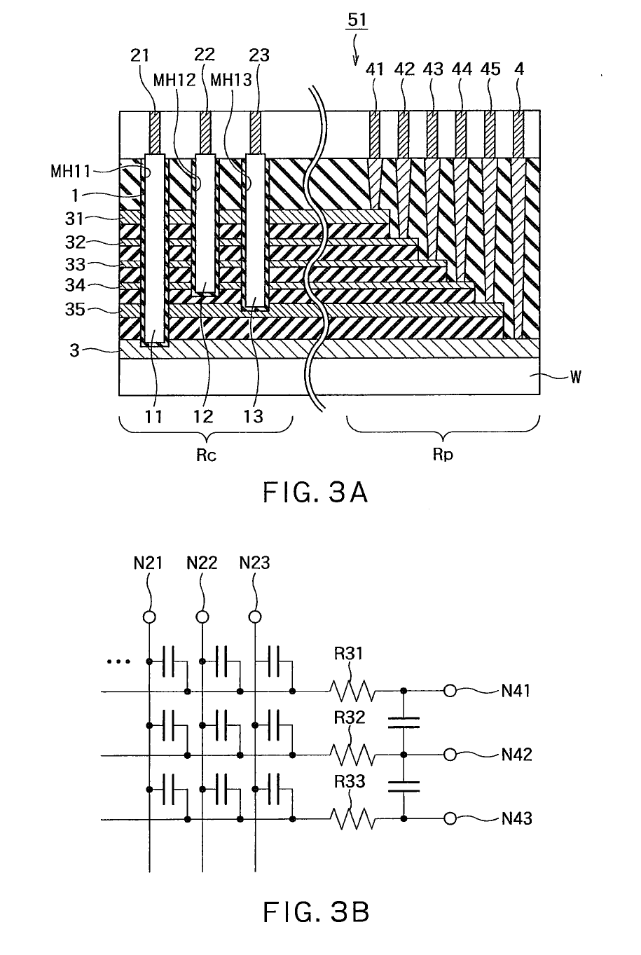

An inspection target sample 51 is formed on the surface layer of the wafer W. A specific configuration of the sample 51 will be described later in detail with reference to FIG. 3A and FIG. 3B.

The electric supply column 54 is connected to the electric supply column control section 64. In response to a control signal from the electric supply column control section 64, the electric supply column 54 generates an electron beam EB1 and then applies the electron beam EB1 to the wafer W. The electric supply column 54 also includes a deflector (not shown) inside, and scans the surface of the wafer W with the electron beam EB1 in accordance with a control signal from the electric supply column control section 64.

In the present embodiment, the electron beam EB1 corresponds to, for example, a first charged particle beam, the electric supply column 54 corresponds to, for example, a first charged particle beam application unit, and the electric supply column control section 64 corresponds to, for example, a deflection control unit.

The detection column 53 is connected to the detection column control section 63. In response to a control signal from the detection column control section 63, the detection column 53 generates an electron beam EB2 and then applies the electron beam EB2 to the wafer W. The detection column 53 also includes a deflector (not shown) inside as in the electric supply column 54, and scans the surface of the wafer W with the electron beam EB2 in accordance with a control signal from the detection column control section 63. In the present embodiment, the electron beam EB2 corresponds to, for example, a second charged particle beam, and the detection column 53 corresponds to, for example, a second charged particle beam application unit.

The secondary electron detector 55 is connected to the signal processing section 65. In response to the application of the electron beam EB2 from the detection column 53, the secondary electron detector 55 detects secondary electrons SE generated from the wafer W, and outputs a signal to the signal processing section 65. In the present embodiment, the secondary electrons SE correspond to, for example, a second charged particle beam.

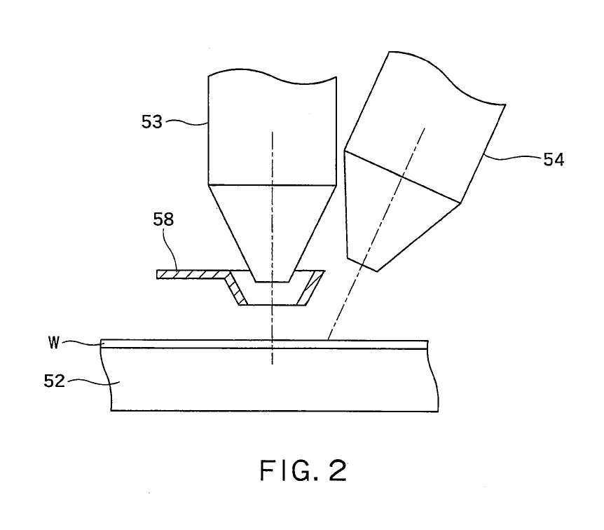

The secondary electrons SE are also generated from the wafer W by the application of the electron beam EB1 from the electric supply column 54, and would cause background noises during an inspection if detected by the secondary electron detector 55. Therefore, the cantilever 58 is provided between the detection column 53 and the wafer W as also shown in a partially enlarged diagram of FIG. 2 to prevent the secondary electrons SE resulting from the electron beam EB1 from entering a detection surface of the secondary electron detector 55. A potential is applied to the cantilever 58 from an unshown electric power supply. Thus, the secondary electrons SE resulting from the electron beam EB1 are blocked. In the present embodiment, the cantilever 58 corresponds to, for example, a blocking member.

The signal processing section 65 is also connected to the judgment section 70. The signal processing section 65 processes a signal sent from the secondary electron detector 55 to generate a potential contrast image representing a potential distribution in the surface of the wafer W, and sends the potential contrast image to the judgment section 70. In the present embodiment, the signal processing section 65 corresponds to, for example, an image acquiring unit.

The judgment section 70 processes the potential contrast image supplied from the signal processing section 65, and thereby detects the abnormality of the sample 51 provided on the surface layer of the wafer W. The judgment section 70 is also connected to the monitor 72 and a memory MR2. The judgment section 70 displays the detection result on the monitor 72 together with the potential contrast image, and records the detection result in the memory MR2. Specific contents of the abnormality detection by the judgment section 70 will be described later in detail. In the present embodiment, the judgment section 70 corresponds to, for example, a judgment unit.

The control computer 50 is connected to the stage drive control section 62, the electric supply column control section 64, the detection column control section 63, the judgment section 70, and a memory MR1. A recipe file in which a series of inspection procedures described later is written is stored in the memory MR1. The control computer 50 reads this recipe file to generate various control signals, and supplies the control signals to the stage drive control section 62, the electric supply column control section 64, the detection column control section 63, and the judgment section 70, thereby controlling the operations of these components.

Here, the sample 51 formed on the surface layer of the wafer W is described with reference to FIG. 3A and FIG. 3B.

FIG. 3A is a sectional view illustrating a device structure of the sample 51. In the present embodiment, the sample 51 is a three-dimensionally stacked NAND flash memory, and has a stack structure in which a plurality of flat-structure NAND-type flash memories are arranged in a vertical direction into a three-dimensional form.

As shown in FIG. 3A, a source potential line 3 is formed on the surface of the wafer W, and insulating films and gate interconnection layers 35, 34, 33, 32, and 31 are alternately formed on the source potential line 3 to construct a stack structure. Combinations of the insulating films and the gate interconnection layers 35, 34, 33, 32, and 31 decrease in area in their peripheral region Rp (the right end in the drawing) from the lower layer to the upper layer to form a stepped shape. Contact plugs 4, 45, 44, 43, 42, and 41 are formed in ohmic contact with the source potential line 3 and the gate interconnection layers 35, 34, 33, 32, and 31 on the source potential line 3 in the peripheral region Rp, respectively.

In the present embodiment, the gate interconnection layers 35, 34, 33, 32, and 31 correspond to, for example, electrically conductive films. In the present specification, the contact plugs (in the present embodiment, the contact plugs 41 to 45, and 4 shown in FIG. 3A) connected at the ends of the gate interconnection layers and at the end of the source potential line are referred to as second contact plugs.

In a cell region Rc of the sample 51, memory holes MH11 to MH13 are formed from the surface toward the source potential line 3. A charge storage layer 1 is formed on the sidewall of each of the memory holes MH11 to MH13. Amorphous silicon is embedded in the memory holes MH11 to MH13 via the charge storage layer 1. Thus, electrode layers 11 to 13 serving as channels are formed. Contact plugs 21 to 23 are provided above the electrode layers 11 to 13, and are in ohmic contact with the top surfaces of the electrode layers 11 to 13.

In the present embodiment, the memory holes MH11 to MH13 correspond to, for example, hole patterns, and the electrode layers 11 to 13 correspond to, for example, electrically conductive films. In the present specification, the contact plugs (in the present embodiment, the contact plugs 21 to 23 shown in FIG. 3A) respectively connected to the electrode layers (in the present embodiment, the electrode layers 11 to 13 shown in FIG. 3A) embedded in the memory holes are referred to as first contact plugs.

The electrode layers 11 to 13 are designed to be in ohmic contact with the source potential line 3 at their bottom surfaces. However, in the present embodiment, a failure has occurred in an etching process to form the memory holes MH11 to MH13, so that the bottom surfaces of the memory holes MH12 and MH13 have not reached the source potential line 3 to be originally connected to. In the example shown in FIG. 3A, the etching to form the memory hole MH13 has stopped at the position of the gate interconnection layer 35, and the etching to form the memory hole MH12 has stopped at the position of the insulating film between the gate interconnection layer 34 and the gate interconnection layer 35.

The electrode layers 11 to 13 are connected by capacitive coupling to the gate interconnection layers 35 to 31 via the charge storage layer 1, respectively. The gate interconnection layers 35 to 31 are ohmically connected to the contact plugs 45 to 41, respectively. The contact plug 4 is a contact plug to the source potential line 3.

FIG. 3B shows an equivalent circuit of a part of the stack structure shown in FIG. 3A. In FIG. 3B, nodes N21 to N23 indicated by circular marks represent the first contact plugs 21 to 23 in FIG. 3A, and nodes N41 to N43 indicated by circular marks represent the second contact plugs 41 to 43. These first and second contact plugs are capacitively-coupled to each other via resistances R31 to R33 of the gate interconnection layers 31 to 33 and the charge storage layer 1.

The sample 51 is preferably inspected when the surface of the stack structure has been planarized by a chemical mechanical polishing (CMP) method after the formation of the stack structure shown in FIG. 3A.

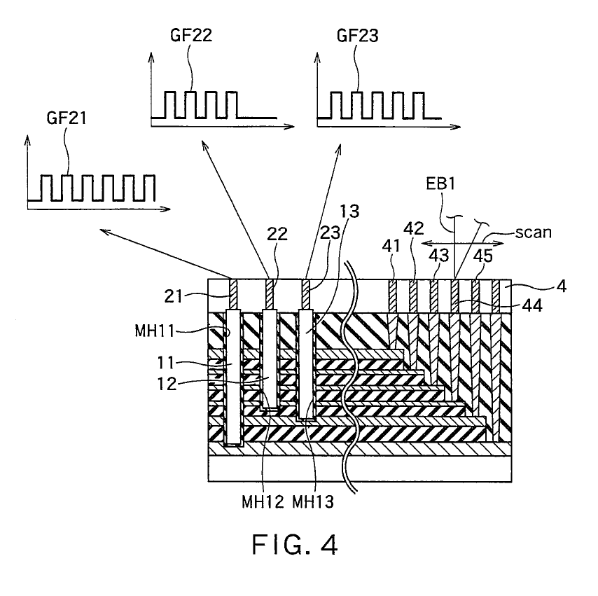

Now, the detection of the abnormality in the memory hole by the inspection apparatus in FIG. 1 is described with reference to FIG. 4 to FIG. 9.

(2) Preprocessing

First, the electric supply column 54 scans the second contact plugs 41 to 45 with the electron beam EB1 in accordance with the control signal sent from the electric supply column control section 64. A secondary electron detector (not shown) provided in addition to the secondary electron detector 55 detects the secondary electrons SE emitted from the surface of the sample 51, and processes a detection signal to acquire surface images of the second contact plugs 4, and 41 to 45. As a result, the locations of the second contact plugs 4, and 41 to 45 are specified, and the electron beam EB1 can thus be applied to any of the second contact plugs 4, and 41 to 45. The electron beam EB1 is then applied to the selected contact plug, so that the potentials of the source potential line 3 and the gate interconnection layers 31 to 35 that are respectively in ohmic contact with the second contact plugs 4, and 41 to 45 can be freely controlled.

(3) Main Processing

The electric supply column 54 sequentially applies the electron beam EB1 to the second contact plugs 4, and 41 to 45. At the same time, a control signal is supplied to the detection column 53 from the detection column control section 63, so that the first contact plugs 31 to 35, and 3 are scanned with the electron beam EB2, and potential contrast images of the first contact plugs 21 to 23 are acquired. An example of the changes of surface potentials of the first contact plugs 21 to 23 with time in this case is shown in graphs GF21 to GF23 in FIG. 4.

As obvious from these graphs GF21 to GF23, the contact plug 21 connected to the electrode layer 11 that fills the normally formed memory hole MH11 always shows a constant contrast for the time in which the electron beam EB1 from the electric supply column 54 is applied to the second contact plugs 41 to 45, and 4. In the meantime, the contact plug 22 connected to the electrode layer 12 that fills the abnormal memory hole MH12 shows no contrast change while the electron beam EB1 from the electric supply column 54 is being applied to the second contact plugs 41 to 44. However, the contact plug 22 shows a different contrast when the electron beam EB1 is applied to the contact plug 45. As a result, the contact plug 22 is detected as an abnormal contact plug. In the same manner, the abnormality of the memory hole MH13 can also be detected if the potentials of the contact plugs including the second contact plug 4 are changed by the electric supply column 54.

As described above, the electron beam EB1 is applied to the surfaces of the second contact plugs connected to the interconnection layers, and the potentials are changed, so that an etching abnormality in the memory holes can be detected. Since the association of the second contact plugs 41 to 45, and 4 with the interconnection layers (the gate interconnection layers 35 to 31 and the source potential line 3) can be known from design data in advance, it is possible to determine the depth at which the etching of the memory hole has stopped.

(4) Function of Electric Supply Column

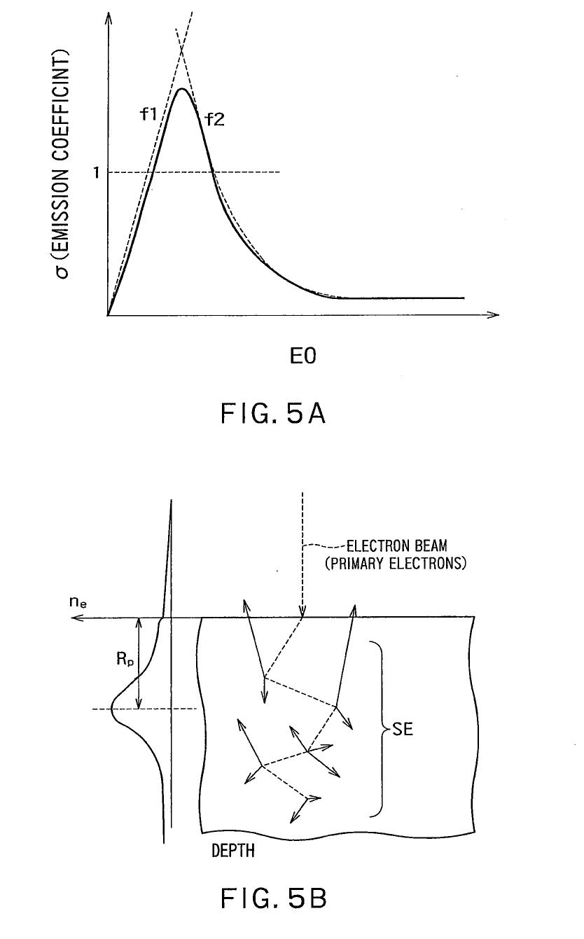

The function of the electric supply column 54 according to the present embodiment is described with reference to FIG. 5A and FIG. 5B. The graph shown in FIG. 5A shows the relation between energy of incoming electrons and a secondary electron emission coefficient. If an emission coefficient σ is 1 or less, a substance is negatively charged because emitted electrons are fewer than incoming electrons. On the other hand, the substance is positively charged if the emission coefficient σ is more than 1.

The incoming electron energy dependence of the secondary electron emission coefficient σ is described with reference to FIG. 5B. As shown in FIG. 5B, if an electron beam enters a substance, the electron beam is repeatedly scattered inside the substance and emits the secondary electrons SE in each scattering process. If the energy of the incoming electrons is high, a large number of scatterings are repeated, and a large number of secondary electrons SE are emitted.

As a result, from the energy conservation law, a total number f1 of the generated secondary electrons SE is provided by

$$f 1 = \frac{{E}_{0}}{{E}_{se}} , \qquad Equation 1$$

wherein E0 is the energy of the incoming electrons, and Ese is the average energy of the secondary electrons SE. Thus, the energy of the incoming electrons becomes higher, and the amount of emitted secondary electrons increases. Meanwhile, the emitted secondary electrons SE have relatively low energy, and are generally said to have the energy of 50 eV or less. Thus, the secondary electrons SE generated inside the substance lose energy before reaching the surface, and disappear because of recombination.

However, if the energy E0 of the incoming electrons increases beyond a given number, the amount of secondary electrons SE generated inside the substance becomes greater. As a result, the amount of emitted secondary electrons rather decreases as in Equation 2 below:

f2=exp(−aRₚ) Equation 2.

f2 indicates the rate at which the secondary electrons SE generated at a given depth reach the surface. “a” represents the absorption coefficient of the secondary electrons SE in a bulk. Rp represents the penetration depth of primary electrons into the bulk shown in FIG. 5B. If a proportionality coefficient of each material is B, Rp depends on the n-th power of the energy of the primary electrons, as shown in Equation 3:

Rₚ=R(E₀)″ Equation 3.

The value of “n” varies by the energy E0 of the primary electrons. For example, at 2 keV to 800 eV, the value of n is approximated by n=4/3. If a probability “A” of final escape from the surface is multiplied by f1 and f2, the relation between the incoming electron energy ED and the generated electron amount σ is obtained as in Equation 4:

$$σ = A \frac{{E}_{0}}{{E}_{se}} exp ( - {aR}_{p} ) . \qquad Equation 4$$

As obvious from the above, the electric supply column 54 has a function to bring the gate interconnection layers in a floating state to a given charged state by controlling the energy of the incoming electrons.

(5) Function of Detection Column

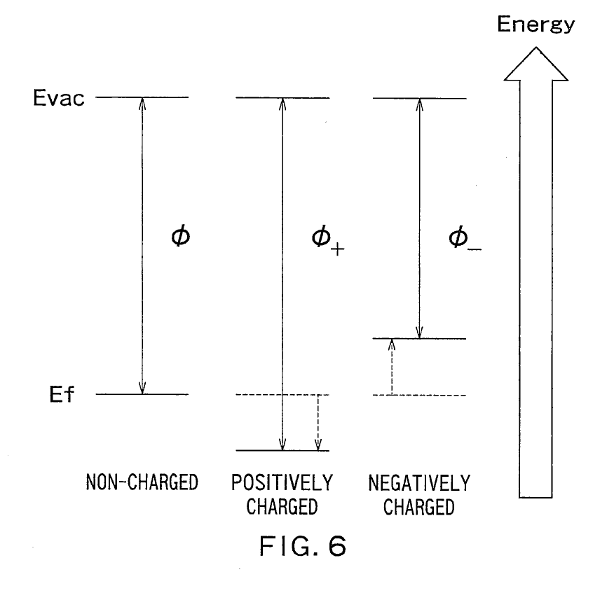

Now, the function of the detection column 53 according to the present embodiment is described with reference to FIG. 6. Each band diagram shown in FIG. 6 shows a vacuum level Evac and a Fermi level Ef in each charged state.

The Fermi level Ef is lower in a positively charged state than in a non-charged state. The Fermi level Ef is higher in a negatively charged state than in the non-charged state. The difference between the Fermi level Ef and the vacuum level Evac is called a work function. The work function and the energy distribution of the secondary electrons SE are known from Equation 5:

$$f ( {E}_{se} ) ∝ \frac{1}{{E}_{0}} \cdot \frac{{E}_{se}}{{( {E}_{se} + φ )}^{4}} . \qquad Equation 5$$

wherein E0 represents the incoming electron energy. Ese represents the secondary electron energy. “φ” represents the work function.

$${\int }_{0}^{∞} f ( {E}_{se} ) ∝ \frac{1}{{E}_{0}} \cdot \frac{1}{{φ}^{2}} \qquad Equation 6$$

is the integration of Equation 5 within a range of secondary electron energy from 0 to infinity, and shows the amount of secondary electrons detected by the secondary electron detector 55.

As described above, if the Fermi level Ef is changed by charging, the emission amount of the secondary electrons SE changes in accordance with Equation 5. In the present embodiment, the contrast of the potential contrast images obtained from the first contact plugs 21 to 23 that are coupled via the charge storage film 1 is changed by the charging of the gate interconnection layers controlled by the electric supply column 54.

(6) Electron Beam Scanning Speed of Electric Supply Column

Now, the optimum electron beam scanning speed of the electric supply column 54 is described. The scanning speed in the present embodiment depends on the resistance of each gate interconnection layer in the stack structure of the sample 51 and capacitances between interconnection layers.

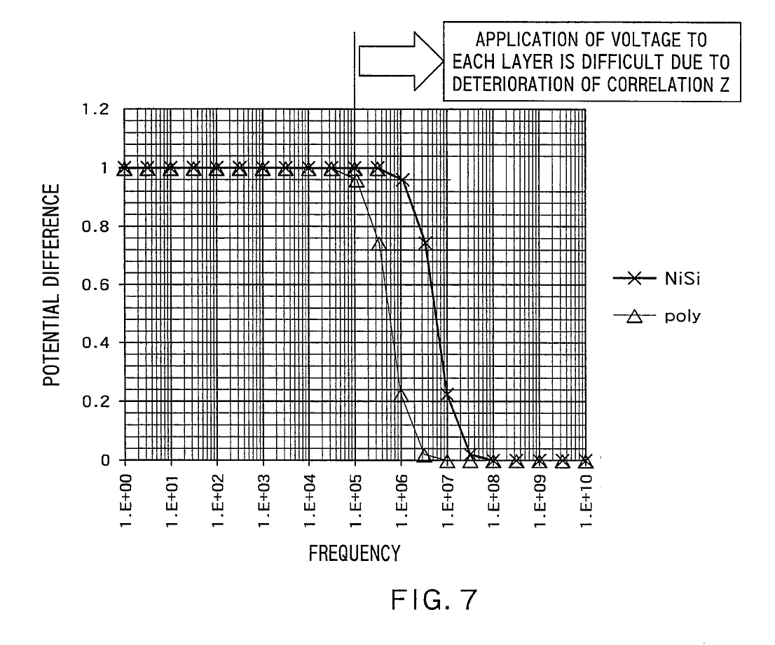

FIG. 7 is an example of a graph showing frequency dependence regarding a potential difference between a potential-controlled gate interconnection layer and a gate interconnection layer adjacent thereto when the capacitance between gate interconnections is about 0.2 pF. A polysilicon layer (“poly” in the graph: 50 ohm/□) and a metal silicide layer (“NiSi” in the graph: 5 ohm/□) that are different in interconnection resistance are shown as parameters.

In the example shown in FIG. 7, impedance Z between the gate interconnection layers decreases on frequency bands of 100 kHz or more. Therefore, it is difficult to independently control the potential of each gate interconnection layer. The frequency shown here indicates a reciprocal number of the interval of the application of the electron beam to one second contact plug. Although not particularly shown, the impedance between the memory hole and the gate interconnection layer also decreases on higher frequency bands. Therefore, the gate interconnection layers are connected with low impedance via the memory hole, and control is more difficult.

On the other hand, the capacitance between the memory hole and the gate interconnection layer is, for example, 20 aF which is four digits lower than the capacitance between the gate interconnection layers. It is therefore possible to quickly follow the potential change of the gate interconnection layers. Consequently, if each of the second contact plugs is scanned at a scanning speed such that the frequency is 100 kHz or less, it is possible to efficiently control the potentials of the second contact plugs and obtain satisfactory potential contrast images.

(7) Abnormality Judgment by Judgment Section

Two examples of the abnormality judgment by the judgment section 70 are specifically described.

### (i) Example 1

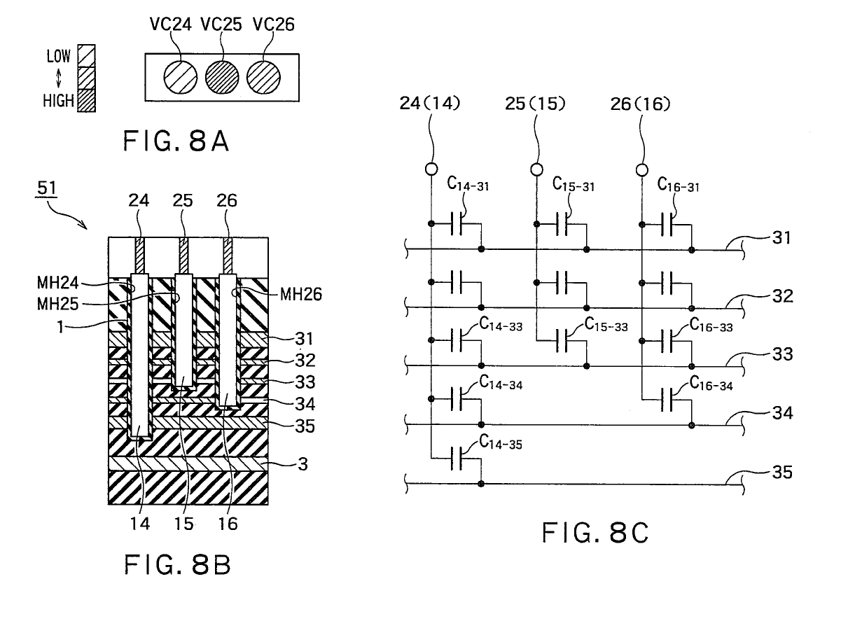

FIG. 8A to FIG. 8C are explanatory diagrams of the abnormality judgment according to Example 1. FIG. 8B is a sectional view showing an example of the memory cell different from the memory cell shown in FIG. 3A among the memory cells provided in the cell region Rc of the sample 51. FIG. 8C shows an equivalent circuit of FIG. 8B. FIG. 8A shows potential contrast images VC24 to VC26 respectively obtained from the contact plugs shown in FIG. 8B when the potential of the gate interconnection layer 32 is changed to a positive charging side.

In the present example, memory holes MH24 to MH26 are formed from the surface of the sample 51 toward the source potential line 3. The charge storage layer 1 is formed on the sidewall of each of the memory holes MH24 to MH26. Amorphous silicon is embedded in the memory holes MH24 to MH26 via the charge storage layer 1. Thus, electrode layers 14 to 16 serving as channels are formed. First contact plugs 24 to 26 are provided on the electrode layers 14 to 16, and are in ohmic contact with the top surfaces of the electrode layers 14 to 16. In the present embodiment, the memory holes MH24 to MH26 correspond to, for example, hole patterns, and the electrode layers 14 to 16 correspond to, for example, electrically conductive layers. The same also applies to Example 2 described below.

The electrode layers 14 to 16 are designed to be in ohmic contact with the source potential line 3 at their bottom surfaces. However, in the present example, a failure has occurred in an etching process to form the memory holes MH24 to MH26, so that the bottom surfaces of the memory holes MH24 and MH26 have not reached the source potential line 3 to be originally connected to. In the example shown in FIG. 8B, the etching to form the memory hole MH25 has stopped at the position before the electrically conductive film 34, and the etching to form the memory hole MH26 has stopped at the position of the insulating film between the electrically conductive film 34 and the insulating film 35.

The electrode layers 14 to 16 are connected by capacitive coupling to the gate interconnection layers 31 to 35 via the charge storage layer 1. The gate interconnection layers 31 to 35 are ohmically connected to unshown second contact plugs.

In the stack structure of the sample 51, all of the gate interconnection layers 31 to 35 are designed to be capacitively connected to the electrode layers 24 to 26 via the charge storage layer 1. Thus, for example, as shown in FIG. 8C which is an equivalent circuit diagram of FIG. 8B, the capacitance between the electrode layer and the gate interconnection layer is higher in the case of the electrode layer that fills the deeply etched memory hole than in the case of the electrode layer that fills the shallowly etched memory hole. As a result, it becomes difficult to follow potential changes.

For example, when seen from the gate interconnection layer 32, a capacitance C₁₅₋₃₁ between the electrode layer 15 and the gate interconnection layer 31, and a capacitance C₁₅₋₃₃ between the electrode layer 15 and the gate interconnection layer 33 are connected to the electrode layer 15 in addition to a capacitance between the electrode layer 15 and the gate interconnection layer 32 itself. A capacitance C₁₆₋₃₁ between the electrode layer 16 and the gate interconnection layer 31, a capacitance C₁₆₋₃₃ between the electrode layer 16 and the gate interconnection layer 33, and a capacitance C₁₆₋₃₄ between the electrode layer 16 and the gate interconnection layer 34 are connected to the electrode layer 16 in addition to a capacitance between the electrode layer 16 and the gate interconnection layer 32 itself. In the same manner, a capacitance C₁₄₋₃₁ between the electrode layer 14 and the gate interconnection layer 31, a capacitance C₁₄₋₃₃ between the electrode layer 14 and the gate interconnection layer 33, a capacitance C₁₄₋₃₄ between the electrode layer 14 and the gate interconnection layer 34, and a capacitance C₁₄₋₃₅ between the electrode layer 14 and the gate interconnection layer 35 are connected to the electrode layer 14 in addition to a capacitance between the electrode layer 14 and the gate interconnection layer 32 itself.

As a result, when the potential of the gate interconnection layer 32 is changed to the positive charging side, the potential contrast image VC24 shown in FIG. 8A which is obtained in the contact plug 24 on the deeply etched memory hole is brightest. This shows that the potential change of the electrode layer 14 is smallest. As in the potential contrast image VC25, the shallowly etched memory hole 25 is most influenced by the charging of the gate interconnection layer 32, and the potential contrast image obtained therefrom is darkest. This shows that the potential change of the electrode layer 15 is greatest.

In this way, an abnormal memory hole can be detected by the comparison of the potential contrast images.

As described above, the capacitance between the abnormal memory hole and the gate interconnection layer is smaller than the capacitance between the normal memory hole and the gate interconnection layer, and the abnormal memory hole tends to follow the external potential change. Therefore, the charging of the first contact plugs 21 to 23 by the detection column 53 also changes depending on the degree of etching.

For example, the energy of the electron beam EB2 of the detection column 53 is selected in such a manner that the first contact plugs 21 to 23 are negatively charged when the gate interconnection layer is positively charged by the electric supply column 54. In this case, the contrasts of the abnormal memory hole and the normal memory hole oppositely change as compared to the case where these memory holes are charged with the same polarity. This leads to deterioration of detection sensitivity.

Accordingly, in the present example, the electron beam energy of the detection column 53 and the electron beam energy of the electric supply column 54 are respectively selected by the detection column control section 63 and the electric supply column control section 64 in such a manner that the charging of the gate interconnection layer by the electric supply column 54 has the same polarity as the charging of the first contact plugs 24 to 26 by the detection column 53.

### (ii) Example 2

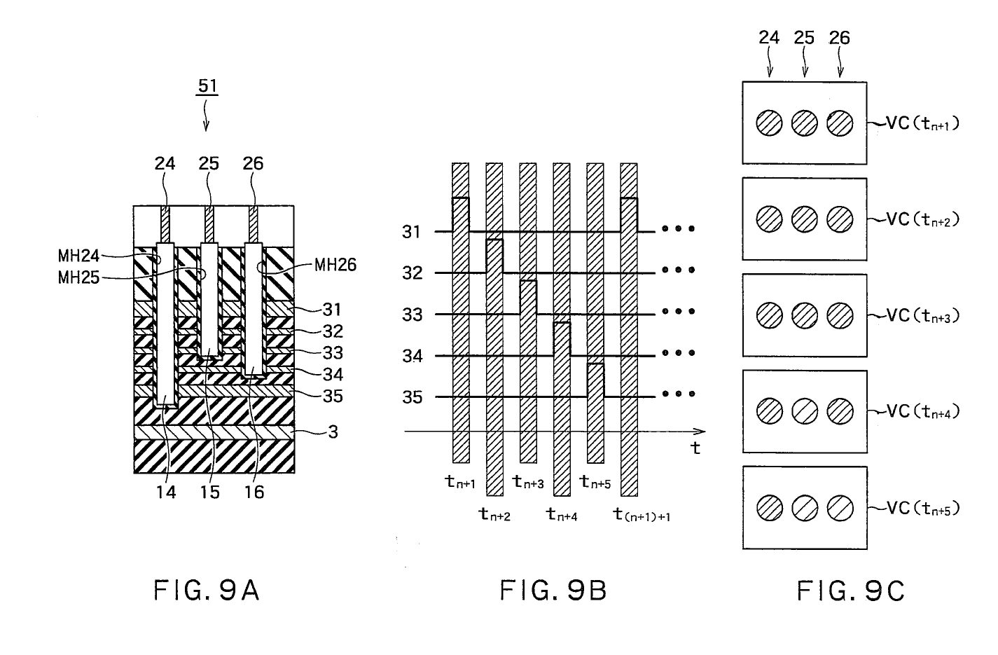

FIG. 9A to FIG. 9C are explanatory diagrams of the abnormality judgment according to Example 2.

FIG. 9A again shows the sectional view of FIG. 8B. FIG. 9B shows an example of a change with time in the potential of each of the gate interconnection layers 31 to 35 which is potential-controlled by the application of the electron beam EB1 to the unshown second contact plugs (see the reference signs 41 to 45, and 4 in FIG. 3A) through the electric supply column 54. FIG. 9C shows potential contrast images VC (tn+1) to VC (tn+5) which are respectively cumulated in times shown in FIG. 9B.

In the present example, the electric supply column 54 repetitively scans the second contact plugs with the electron beam EB1, and the detection column 53 scans the first contact plugs 24 to 26 with the electron beam EB2. Thus, the judgment section 70 cumulates the potential contrast images obtained by the signal processing section 65 via the secondary electron detector 55 whenever a time t passes. The cumulated images are compared with one another. In the present example, both the first contact plugs 24 to 26 and the second contact plugs are positively charged. When both are negatively charged, the brightness/darkness of the obtained potential contrast images is opposite to that shown in FIG. 9C.

In the example shown in FIG. 9A, all of the memory holes MH14 to MH16 are etched to at least the position of the gate interconnection layer 33. Therefore, as shown in FIG. 9C, it can be recognized that all the parts corresponding to the regions of the first contact plugs 24 to 26 are dark and have high potentials from the cumulated image VC(tn+1) to the cumulated image VC(tn+3).

On the other hand, the bottom surface of the memory hole

MH25 does not reach the gate interconnection layer 34 because of an etching failure, and is located in the insulating film between the gate interconnection layer 33 and the gate interconnection layer 34. Thus, in the cumulated image VC (tn+4), the part corresponding to the region of the first contact plug 25 cannot follow the potential drop of the gate interconnection layer 34 caused when electricity is supplied to the second contact plugs on the gate interconnection layer 34. Therefore, the contrast in this part does not change. On the other hand, the normally formed first contact plugs 24 and 26 follow the potential drop, and thus change into a dark state. This proves the etching failure of the memory hole MH25. In the abnormality judgment based on the cumulated image VC (tn+4) according to the present example, the gate interconnection layer 34 corresponds to, for example, the electrically conductive film corresponding to a time when a change has been found, and the gate interconnection layer 33 corresponds to, for example, the electrically conductive film corresponding to a time immediately before the time when the change has been found.

Similarly, the bottom surface of the memory hole MH26 does not reach the gate interconnection layer 35 because of an etching failure, and is located in the insulating film between the gate interconnection layer 34 and the gate interconnection layer 35. Thus, in the cumulated image VC(tn+5), the part corresponding to the region of the first contact plug 26 as well as the part corresponding to the region of the first contact plug 25 cannot follow the potential drop. Therefore, the contrast in these parts does not change. This means that the potential of the first contact plug 26 has dropped when electricity is supplied to the second contact plug on the gate interconnection layer 35, and proves the etching failure of the memory hole MH26. In the abnormality judgment based on the cumulated image VC (tn+5) according to the present example, the gate interconnection layer 35 corresponds to, for example, the electrically conductive film corresponding to a time when a change has been found, and the gate interconnection layer 34 corresponds to, for example, the electrically conductive film corresponding to a time immediately before the time when the change has been found.

Since the depth of each of the gate interconnection layers 31 to 35 can be easily related with the positions of the first contact plugs 24 to 26 in accordance with design information in advance, the potential contrast images VC (tn+1) to VC (tn+5) correspond to plane slice images at the etching depths of the memory holes MH24 to MH26.

As described above, according to the present example, the integrated image of the potential contrast is acquired, so that a memory hole having an etching failure can be accurately detected. The detection result can be used to evaluate the in-plane uniformity of the wafer W and the allowance of an etching margin.

The inspection apparatus according to at least one embodiment described above includes the electric supply column 54 configured to control the potential of each gate interconnection layer by applying the electron beam EB1 to the second contact plugs of the sample 51 of the stack structure in which the gate interconnection layers and the insulating films alternately stacked, the detection column 53 configured to apply the electron beam EB2 to the first contact plugs, the signal processing section 65 configured to process the signal of the secondary electrons SE detected from the secondary electron detector 55 to acquire a potential contrast image, and the judgment section 70 configured to judge the abnormality of the memory hole from the acquired potential contrast image. Therefore, it is possible to accurately detect the abnormality of the memory hole, and specify the etching depth of the abnormal memory hole. It is also possible to conduct a wide-range inspection with a high throughput because the stage 52 is included and moves the wafer W on the stage 52 in the three-dimensional space and at a given rotation angle to acquire the potential contrast image using the electron beam EB2.

(B) Inspection Method

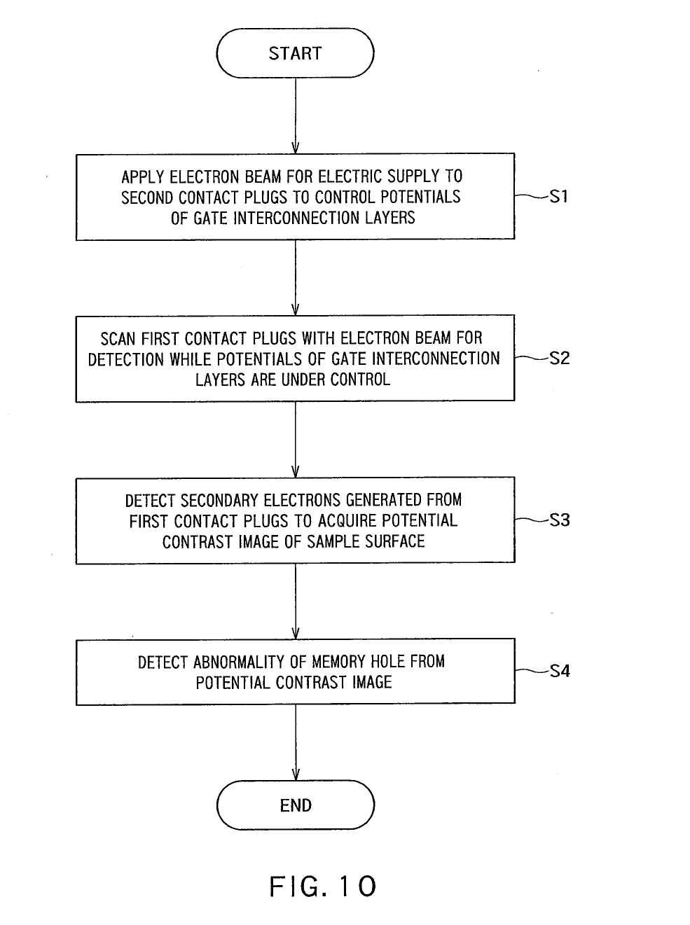

An inspection method according to one embodiment is described with reference to FIG. 10. FIG. 10 is a flowchart showing a general procedure of an inspection method according to the present embodiment. In the present embodiment, the sample 51 shown in FIG. 3A is described by way of example as an inspection target sample.

First, the electron beam EB1 for electric supply is applied to the second contact plugs 41 to 45, and 4 to control the potentials of the gate interconnection layers 31 to 35 and the source potential line 3 (step S1).

While the potentials of the gate interconnection layers 31 to 35 and the source potential line 3 are under control, the first contact plugs 21 to 23 are then scanned with the electron beam EB2 for detection (step S2).

In response to the application of the electron beam EB2, the secondary electrons SE are generated from the cell region Rc of the sample 51 in which the first contact plugs 21 to 23 are formed. Therefore, the secondary electrons SE are detected to acquire a potential contrast image of the surface of the sample 51 (step S3).

Whether the memory holes MH11 to MH13 in which the electrode layers 11 to 13 are respectively embedded are abnormal is judged from the acquired potential contrast image. When an abnormality is detected, the etching depth of the memory hole is calculated and output (step S4).

According to the inspection method in at least one embodiment described above, the electron beam EB1 is applied to the second contact plugs of the sample 51 of the stack structure in which the gate interconnection layers and the insulating films alternately stacked. Thus, while the potential of each gate interconnection layer is under control, the electron beam EB2 is applied to the first contact plugs. The secondary electrons SE generated from the first contact plugs are detected to acquire a potential contrast image, and the abnormality of the memory hole is judged from the acquired potential contrast image. Therefore, it is possible to accurately detect the abnormality of the memory hole, and specify the etching depth of the abnormal memory hole.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions.

For example, although the electrode layer provided in the memory hole is connected to each gate electrode layer via the charge storage layer 1 in the case described by way of example in the above embodiments, the present invention is not limited to such embodiments. For example, the present invention is also applicable when each gate electrode layer is connected to each gate electrode layer via a variable resistance film. Although the electron beam column which applies the electron beam EB1 has been described as the electric supply column 54 by way of example in the above embodiments, the configuration of the electric supply column 54 is not limited thereto. For example, a focused ion beam (FIB) column which applies an ion beam may be used. In this case, the ion beam corresponds to, for example, the first charged particle beam.

The accompanying claims and their equivalents are intended to cover such forms or modifications as would fall within the scope and spirit of the inventions.

1. An inspection apparatus comprising:
a first charged particle beam application unit configured to apply a first charged particle beam to second contact plugs of a sample to control potentials of electrically conductive films, the sample comprising a stack structure, electrically conductive layers, and first and second contact plugs, the electrically conductive films and insulating films being alternately stacked in the stack structure, the electrically conductive layers being provided in hole patterns formed in the stack structure in a stacking direction and being respectively connected to the electrically conductive films via a capacitance or a resistance, the first contact plugs being respectively connected to the electrically conductive layers, and the second contact plugs being connected to the electrically conductive layers;
a second charged particle beam application unit configured to apply a second charged particle beam to the first contact plugs;
a detector configured to detect secondary charged particles generated from a surface of the stack structure to output a signal;
an image acquiring unit configured to process the signal to acquire a first image of the sample surface; and
a judgment unit configured to judge an abnormality of the hole pattern from the acquired first image.

2. The apparatus of claim 1, further comprising a deflection control unit configured to deflect the first charged particle beam to scan the second contact plugs.

3. The apparatus of claim 2,
wherein the deflection control unit deflects the second charged particle beam at a speed of 100 kHz or less.

4. The apparatus of claim 1,
wherein the judgment unit compares the first images mutually among the hole patterns to judge the abnormality of the hole pattern.

5. The apparatus of claim 1,
wherein the first and second charged particle beam application units apply the first and second charged particle beams in a condition in which both the first and second contact plugs are charged with the same polarity.

6. The apparatus of claim 2,
wherein the judgment unit integrates the first image to obtain a second image whenever the first charged particle beam application unit scans each of the second contact plugs with the first charged particle beam, and the judgment unit specifies the abnormality of the hole pattern and the position of its bottom surface, from the obtained second image.

7. The apparatus of claim 6,
wherein when a change is found between the hole patterns in the second image, the judgment unit judges that the hole pattern located at a place where the change has been found is abnormal.

8. The apparatus of claim 7,
wherein the judgment unit judges that the bottom surface is located between the electrically conductive film corresponding to a time when the change has been found, and the electrically conductive film corresponding to a time immediately before the time when the change has been found.

9. The apparatus of claim 1, further comprising a blocking member which is provided between the second charged particle beam application unit and the sample and which prevents the secondary charged particles emitted from the sample in response to the application of the first charged particle beam from entering the detector.

10. The apparatus of claim 1,
wherein the first charged particle beam is an ion beam, and the second charged particle beam is an electron beam.

11. The apparatus of claim 1,
wherein both the first and second charged particle beams are electron beams.

12. A method of inspecting a sample, the sample comprising a stack structure, electrically conductive layers, first and second contact plugs, the electrically conductive films and insulating films being alternately stacked in the stack structure, electrically conductive layers being provided in hole patterns formed in the stack structure in a stacking direction and being respectively connected to the electrically conductive films via a capacitance or a resistance, the first contact plugs being respectively connected to the electrically conductive layers, and the second contact plugs being connected to the electrically conductive layers, the method comprising:
applying a first charged particle beam to the second contact plugs to control the potentials of the electrically conductive films;
applying a second charged particle beam to the first contact plugs;
detecting secondary charged particles generated from the surface of the stack structure and then outputting a signal;
processing the signal to acquire a first image of the sample surface; and
judging an abnormality of the hole pattern from the acquired first image.

13. The method of claim 12, further comprising deflecting the first charged particle beam to scan the second contact plugs.

14. The method of claim 13,
wherein the deflection speed is 100 kHz or less.

15. The method of claim 12,
wherein the abnormality of the hole pattern is judged by mutually comparing the first images among the hole patterns.

16. The method of claim 12,
wherein the first and second charged particle beams are applied in such a manner that both the first and second contact plugs are charged with the same polarity.

17. The method of claim 13,
wherein the judging an abnormality comprises integrating the first image to obtain a second image whenever each of the second contact plugs is scanned with the first charged particle beam, and specifying the abnormality of the hole pattern and the position of its bottom surface, from the obtained second image.

18. The method of claim 17,
wherein the judging an abnormality comprises judging that the hole pattern located at a place where a change has been found is abnormal when the change is found between the hole patterns in the second image.

19. The method of claim 18,
wherein the judging an abnormality comprises judging that the bottom surface is located between the electrically conductive film corresponding to a time when the change has been found, and the electrically conductive film corresponding to a time immediately before the time when the change has been found.

20. The method of claim 12,
wherein both the first and second charged particle beams are electron beams.
